(19) United States
(12) Patent Application Publication
(10) Pub. No.: US 2025/0372856 A1
(43) Pub. Date: Dec. 4, 2025

(54) RF DEVICE AND ELECTRONIC APPARATUS

(71) Applicant: UNIVERSAL SCIENTIFIC INDUSTRIAL ( SHANGHAI ) CO., LTD., SHANGHAI (CN)

(72) Inventor: KUAN-HSING LI, SHANGHAI (CN)

(21) Appl. No.: 19/005,185

(22) Filed: Dec. 30, 2024

(30) Foreign Application Priority Data
May 31, 2024 (CN) 202410706555.1

(51) Int. Cl. H01P 3/12

(52) U.S. Cl. CPC H01P 3/121

(57) ABSTRACT

An RF device and an electronic apparatus are provided. The RF device includes: a substrate assembly, a first metal structure provided on one side of the substrate assembly, and a metal shielding cover provided on the substrate assembly and shielding the first metal structure. The first metal structure includes a first bending structure. The first bending structure includes a first part and a second part. The second part is connected to the first part. An included angle is defined between the second part and the first part. The substrate assembly receives an RF signal, and the RF signal is transmitted through the substrate assembly, the first metal structure and the metal shielding cover.

### CROSS-REFERENCE TO RELATED PATENT APPLICATION

This application claims the benefit of priority to China Patent Application No. 202410706555.1, filed on May 31, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an RF device and an electronic apparatus, and more particularly to an RF device with low energy loss and an electronic apparatus using the RF device.

### BACKGROUND OF THE DISCLOSURE

With the evolution of mobile communication networks to accommodate more bandwidth for growing digital applications, the 5G generation has expanded into the millimeter-wave frequency bands of the frequency range 2 (FR2) in addition to using the limited bandwidth of sub-6 GHz in the frequency range 1 (FR1). Recently, the 3GPP standard has also been extended to include 71 GHZ (Band n263). However, at such high frequency ranges, testing the RF stripline within the substrate leads to more severe energy loss.

In recent years, in order to reduce insertion loss, designs using the substrate-integrated waveguide (SIW) have been adopted to significantly increase the conductor area, thereby reducing the impact of smaller traditional conductor surface areas and surface roughness.

The transmission principle of the substrate-integrated waveguide (SIW) is similar to that of traditional rectangular waveguides, in which rows of metal through-holes are arranged in the dielectric substrate to confine the electromagnetic waves to propagate within the rectangular cavity formed by the rows of metal through-holes and upper and lower metal layers.

Although the substrate-integrated waveguide (SIW) has the advantage of lower loss compared to a traditional RF stripline, there is still considerable energy loss when electromagnetic waves are transmitted through the substrate medium.

### SUMMARY OF THE DISCLOSURE

In order to solve the above-mentioned problems, one of the technical aspects adopted by the present disclosure is to provide an RF device in response to the deficiencies of the existing technology. The RF device includes: a substrate assembly, a first metal structure provided on one side of the substrate assembly, and a metal shielding cover provided on the substrate assembly and shielding the first metal structure. The first metal structure includes a first bending structure, the first bending structure includes a first part and a second part, the second part is connected to the first part, and an included angle is defined between the second part and the first part. The substrate assembly receives an RF signal, and the RF signal is transmitted through the substrate assembly, the first metal structure, and the metal shielding cover.

In order to solve the above-mentioned problems, another one of the technical aspects adopted by the present disclosure is to provide an electronic apparatus. The electronic apparatus includes: a control circuit and at least one RF device connected to the control circuit. The at least one RF device includes: a substrate assembly, a first metal structure provided on one side of the substrate assembly, and a metal shielding cover provided on the substrate assembly and shielding the first metal structure. The first metal structure includes a first part, a second part, and a third part. The second part is connected to the first part, the third part is connected to the second part, the first metal structure is in a r shape, and the first and third parts of the first metal structure are connected to the substrate assembly. The control circuit provides an RF signal to the substrate assembly of the RF device, and the RF signal is transmitted through the substrate assembly, the first metal structure, and the metal shielding cover for a testing procedure.

One of the beneficial effects of the present disclosure is that, the RF device and the electronic apparatus provided by the present disclosure can effectively reduce RF energy loss, decrease the size of the RF device, and provide directional bending of the electric field of the RF signal. Furthermore, the RF device and the electronic apparatus of the present disclosure can further reduce the cost of device production, thereby improving efficiency for the production process.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic diagram of an RF device according to a first embodiment of the present disclosure;

FIG. 2 is another schematic diagram of the RF device according to the first embodiment of the present disclosure;

FIG. 3 is a front perspective view of the RF device according to the first embodiment of the present disclosure;

FIG. 4 is a partial side view of the RF device according to the first embodiment of the present disclosure;

FIG. 5 is a diagram illustrating the distribution of electric field strength of the RF device according to the first embodiment of the present disclosure;

FIG. 6 is a diagram illustrating the distribution of electric field strength along cross-sectional line VI-VI in FIG. 5;

FIG. 7 is an S-parameter performance chart of the RF device according to the first embodiment of the present disclosure; and

FIG. 8 is a schematic diagram of an electronic apparatus according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether or not a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

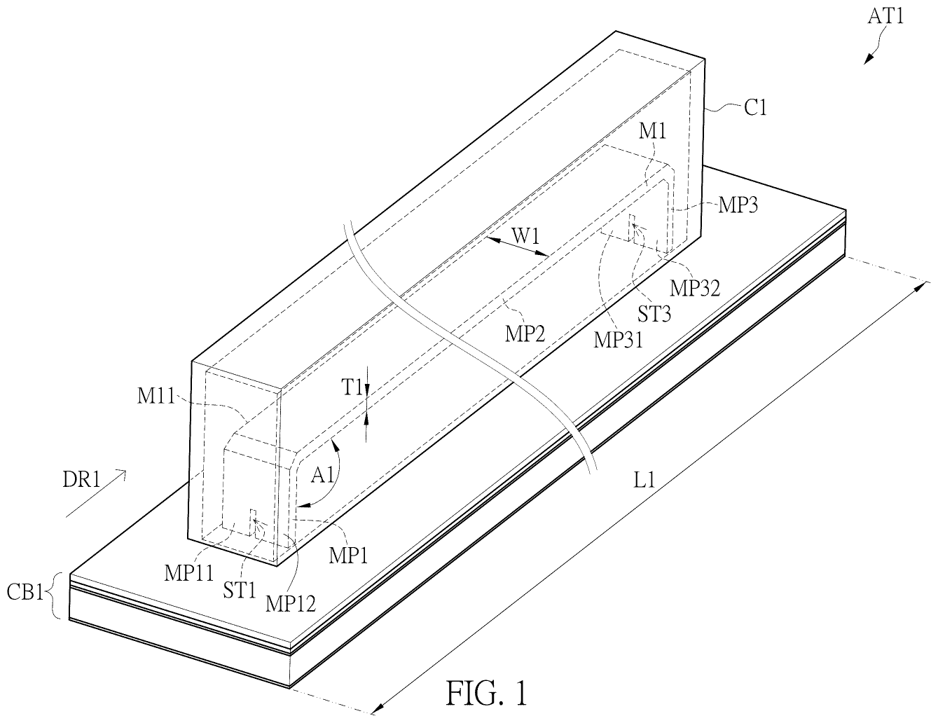

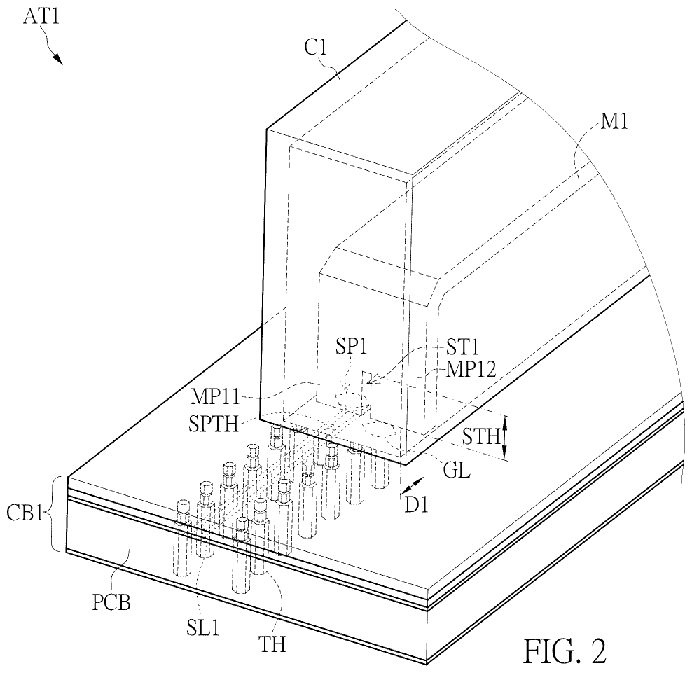

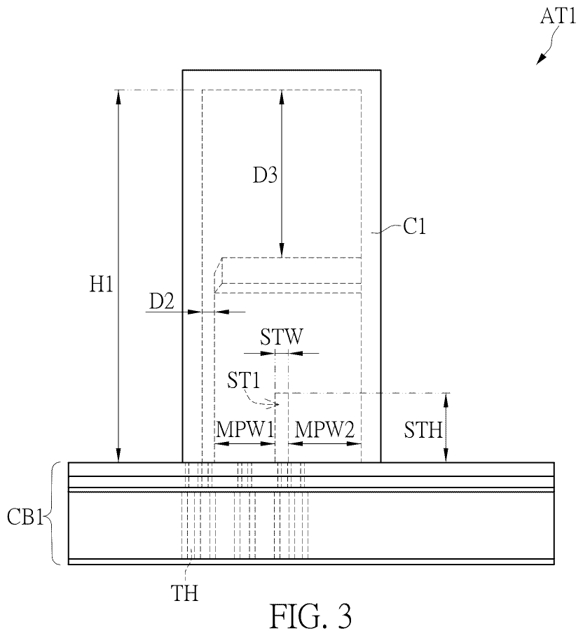

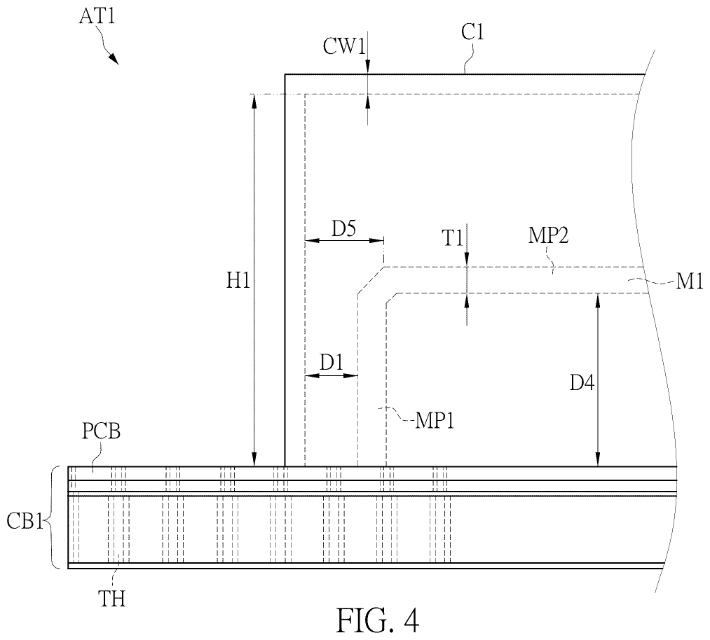

Reference is made to FIGS. 1, 2, 3, and 4. FIG. 1 is a schematic diagram of an RF device according to a first embodiment of the present disclosure, FIG. 2 is another schematic diagram of the RF device according to the first embodiment, FIG. 3 is a front perspective view of the RF device according to the first embodiment, and FIG. 4 is a partial side view of the RF device according to the first embodiment.

In this embodiment, an RF device AT1 is provided.

The RF device AT1 includes a substrate assembly CB1, a first metal structure M1, and a metal shielding cover C1.

The first metal structure M1 is provided on one side of the substrate assembly CB1. The metal shielding cover C1 is provided on the substrate assembly CB1 and completely shields the first metal structure M1.

The first metal structure M1 includes at least one first bending structure M11. The first bending structure M11 includes a first part MP1 and a second part MP2. The second part MP2 is connected to the first part MP1. An included angle A1 is formed between the second part MP2 and the first part MP1. In this embodiment, the included angle between the second part MP2 and the first part MP1 is 90 degrees. That is, the first part MP1 is perpendicular to the substrate assembly CB1, and the second part MP2 is parallel to the substrate assembly CB1.

The first metal structure M1 further includes a third part MP3. The third part MP3 is connected to the second part MP2 and is provided on the substrate assembly CB1.

The first metal structure M1 is a metal sheet structure formed in an inverted U-shape. Additionally, the metal shielding cover C1 is a rectangular hollow structure, and completely shields the first metal structure M1.

Furthermore, one side of the second part MP2 of the first metal structure M1 is provided on the metal shielding cover C1, but another side of the second part MP2 of the first metal structure M1 is spaced apart from an inner wall of the metal shielding cover C1 by a distance and is not directly connected to the inner wall of the metal shielding cover C1.

The substrate assembly CB1 includes at least one multilayer circuit board PCB, a solder pad SP1, at least one signal metal through-hole SPTH, and a plurality of metal through-holes TH. The at least one signal metal through-hole SPTH and the plurality of metal through-holes TH are provided in the multilayer circuit board PCB. A stripline SL1 is provided in a middle layer of the multilayer circuit board PCB and is connected to the solder pad SP1 in a top layer. Additionally, the top layer of the multilayer circuit board PCB includes a ground layer GL. In this embodiment, the stripline SL1 is an RF stripline, and the stripline SL1 of the substrate assembly CB1 is connected to a control circuit (not shown) to receive an RF signal.

In this embodiment, the multilayer circuit board PCB is a four-layer substrate circuit board, and the architecture is symmetric at two ends of the multilayer circuit board PCB. The plurality of signal metal through-holes SPTH and two rows of the plurality of metal through-holes TH are provided in the multilayer circuit board PCB and on both sides of the long side of the multilayer circuit board PCB. The stripline SLI transmits an RF signal through one side of the multilayer circuit board PCB.

The RF signal is transmitted within the metal shielding cover C1 through the substrate assembly CB1 and the first metal structure M1. The electric field vector distribution of the RF signal can also form a bent electric field vector within the cavity of the metal shielding cover C1 through the first metal structure M1. The at least one signal metal through-hole SPTH and the solder pad SP1 are provided on both sides of the long side of the substrate assembly CB1.

A length L1 of the substrate assembly CB1 in a first direction DR1 is 60 mm. A thickness T1 of the first metal structure M1 is 0.2 mm. A width W1 of the first metal structure M1 is 1.05 mm.

The first part MP1 of the first metal structure M1 is provided on the substrate assembly CB1. The first part MP1 of the first metal structure M1 includes a first notch ST1. A width STW of the first notch ST1 is 0.1 mm. A height STH of the first notch ST1 is 0.45 mm. One side of the first metal structure M1 is connected to the metal shielding cover C1.

The first part MP1 of the first metal structure M1 includes a first subsection MP11 and a second subsection MP12 on both sides of the first notch ST1. The first subsection MP11 is connected to the solder pad SP1 and at least one signal metal through-hole SPTH to receive the RF signal from the control circuit (not shown). A distance D2 between the first subsection MP11 and the inner wall of the metal shielding cover C1 is 0.1 mm. The second subsection MP12 is connected to the other side of the inner wall of the metal shielding cover C1. Additionally, the second subsection MP12 is connected to the ground layer GL of the surface of the multilayer circuit board PCB of the substrate assembly CB1 through solder. A width MPW1 of the first subsection MP11 is 0.45 mm. A width MPW2 of the second subsection MP12 is 0.55 mm.

In addition to the first part MP1 of the first metal structure M1 including the first notch ST1, the third part MP3 also includes a second notch ST3. A dimension of the second notch ST3 is the same as the dimension of the first notch ST1.

Similarly, the stripline SL1 is also provided on the underside of the third part MP3. Likewise, a solder pad (not shown), at least one signal metal through-hole (not shown), and a plurality of metal through-holes (not shown) are also provided on one side of the third part MP3 of the first metal structure M1 of the substrate assembly CB1. Furthermore, the third part MP3 is also divided into a first subsection MP31 and a second subsection MP32 by the second notch ST3. The first subsection MP31 of the third part MP3 is connected to a solder pad (not shown) and at least one signal metal through-hole (not shown).

A distance D1 between the first part MP1 of the first metal structure M1 and the inner wall of the metal shielding cover C1 is 0.4 mm. A distance D2 from a junction between the first part MP1 and the second part MP2 of the first metal structure M1 to the inner wall of the metal shielding cover C1 is 0.1 mm.

Reference is made to FIG. 4. An internal height H1 of the metal shielding cover C1 is 2.75 mm. A wall thickness CW1 of the metal shielding cover C1 is 0.15 mm. Furthermore, a distance D3 between the upper side of the second part MP2 of the first metal structure M1 and the inner wall of the upper side of the metal shielding cover C1 is 1.275 mm. A distance D4 between the lower side of the second part MP2 of the first metal structure M1 and the circuit board PCB of the substrate assembly CB1 is 1.275 mm. That is, in this embodiment, the second part MP2 of the first metal structure M1 is positioned in the middle of the metal shielding cover C1. In this embodiment, the values of distances, wall thickness, height, and length are provided for reference only and can be scaled proportionally or adjusted based on the requirements of the RF signal, and are not limited in the present disclosure.

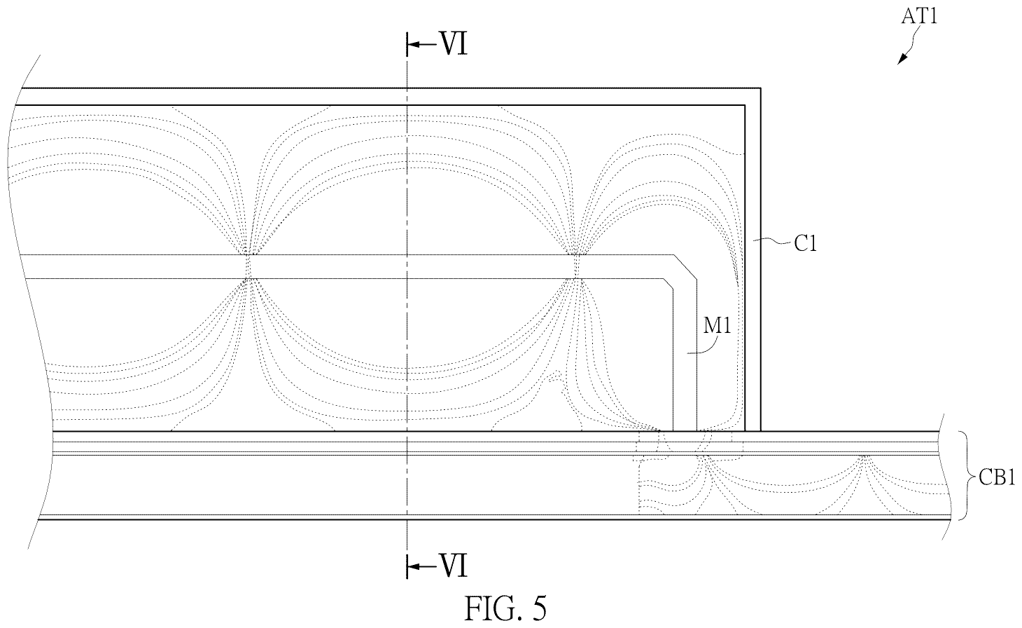

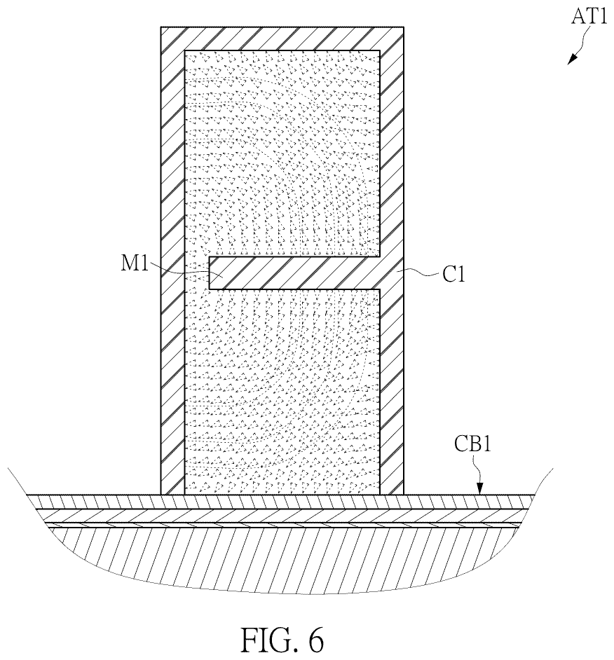

Reference is made to FIGS. 5 and 6. FIG. 5 is a diagram illustrating the distribution of electric field strength of the RF device according to the first embodiment of the present disclosure and FIG. 6 is a diagram illustrating the distribution of electric field strength along sectional line VI-VI in FIG. 5.

From the electric field strength distribution diagram in FIG. 5, it can be seen that, when the electromagnetic waves propagate, the electric field strength is concentrated within the cavity of the metal shielding cover C1. From the side view, it can be seen that, after the RF signal enters the stripline SL1 in the inner layer, the energy of the RF signal is transmitted to the first metal structure M1 through the signal metal through-hole SPTH. As shown in FIG. 6 (sectional side view taken along VI-VI), under the enclosure of the metal shielding cover C1, the RF signal forms bent electric field vectors.

Furthermore, since the RF signal propagates through the air within the metal shielding cover C1 as the transmission medium, the loss of the RF signal can be reduced, thereby enhancing the loss characteristics.

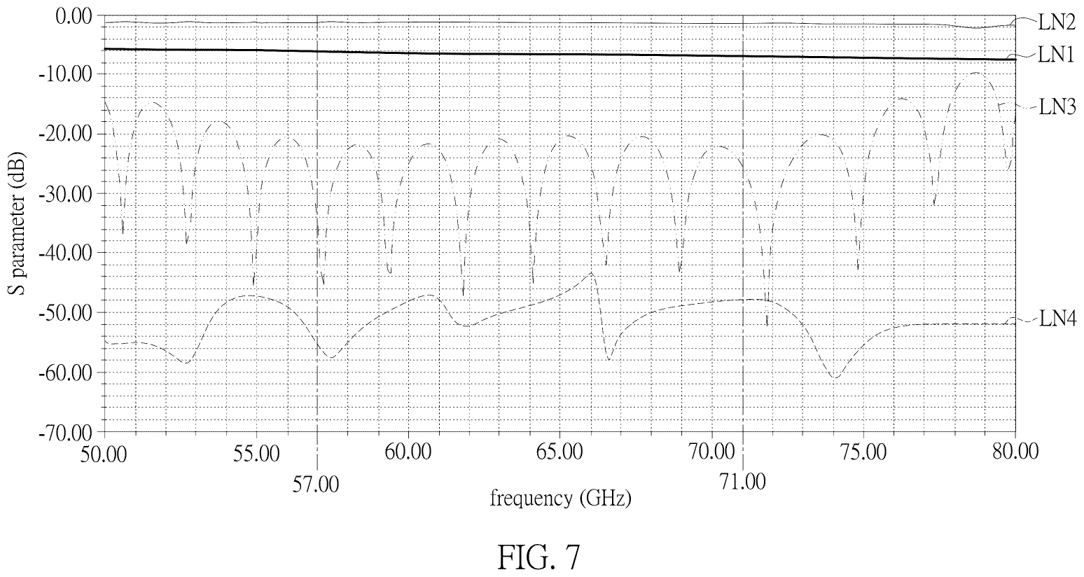

Referring to FIG. 7, FIG. 7 is an S-parameter performance chart of the RF device according to the first embodiment of the present disclosure.

From the S-parameter performance chart in FIG. 7, it can be seen that the insertion loss of the RF device AT1 (curve LN2) of this embodiment is nearly 5.0 dB to 5.5 dB less than that of the signal stripline (curve LN1) with the same length of 60 mm, and the curve LN3 has a return loss of more than 15 dB (the return loss even reaches 20 dB) in the n263 frequency band (from 57 GHz to 71 GHZ) of the latest frequency range 2 (FR2). That is to say, the RF device of this embodiment is very suitable for applications in the 5G millimeter wave or higher frequency bands. Curve LN4 represents the return loss curve for the 60 mm stripline.

The RF device AT1 of this embodiment is a folded substrate integrated waveguide (folded SIW) design that is vertically oriented and made of metal, which utilizes the low loss characteristics of air within the cavity of the metal shielding cover C1, characterized by a low loss tangent (tan(δ) or dissipation factor (DF)), such that the RF signal can use the air in the cavity as a propagation medium, thereby improving the low-loss characteristics of the substrate integrated waveguide (SIW) for applications in frequency range 2 (FR2) or higher.

Folded substrate integrated waveguides of existing literature and industry designs have the following characteristics of: (1) using the substrate as the signal transmission medium, but the substrate medium has excessive loss and requires the selection of more expensive low dissipation factor (low Df) materials; and (2) not suitable for higher frequency bands within the 5G NR frequency range 2 (FR2), such as band (57 GHz to 71 GHz) within FR2. Moreover, the folded substrate integrated waveguide (folded SIW) requires the use of a large amount of three-layer circuit board layout. That is, the stripline (an RF trace) in the folded substrate integrated waveguide requires a very long distance (e.g., several tens of centimeters), which translates to hundreds of millimeters (mm), such that a very large circuit board area is needed.

Therefore, the RF device AT1 of this embodiment can effectively reduce the length of use of the stripline and achieve nearly 5.0 dB to 5.5 dB less insertion loss. Furthermore, the RF device AT1 of this embodiment meets the standard specifications for return loss within the 5G frequency range 2 (FR2) band n263 (57˜71GHz), and is suitable for application in millimeter-wave frequencies or higher frequencies.

### Second Embodiment

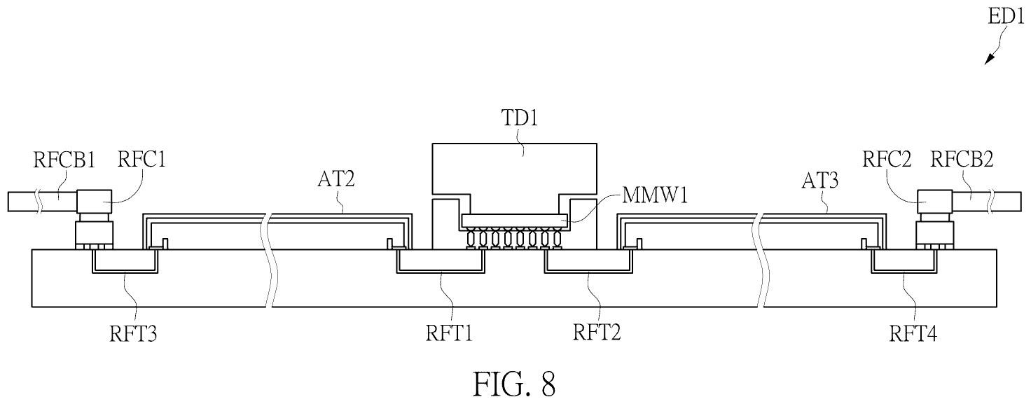

Referring to FIG. 8, FIG. 8 is a schematic diagram of an electronic apparatus according to a second embodiment of the present disclosure.

In this embodiment, an electronic apparatus ED1 is provided. The electronic apparatus ED1 is an automatic test apparatus (ATE).

The electronic apparatus ED1 includes a test device TD1, a millimeter-wave module MMW1, a first RF device AT2, and a second RF device AT3. The test device TD1 is connected to the millimeter-wave module MMW1.

The first RF device AT2 and the second RF device AT3 are positioned on two sides of the millimeter-wave module MMW1. The first RF device AT2 is connected to the millimeter-wave module MMW1 through a first RF trace RFT1. The second RF device AT3 is connected to the millimeter-wave module MMW1 through a second RF trace RFT2. The millimeter-wave module MMW1 is electrically connected to the test device TD1 through a connector (a socket) for receiving signals.

The first RF device AT2 is connected to a first RF connector RFC1 through a third RF trace RFT3. The second RF device AT3 is connected to a second RF connector RFC2 through a fourth RF trace RFT4. The first RF connector RFC1 and the second RF connector RFC2 are connected to a first RF cable RFCB1 and a second RF cable RFCB2, respectively.

In this embodiment, the millimeter-wave module MMW1, the first RF device AT2, and the second RF device AT3 are positioned on the same circuit board.

The structure and function of the first RF device AT2 and the second RF device AT3 are the same as those of the first RF device AT1 of the first embodiment and are not reiterated in detail herein. In this embodiment, the test device TD1 can constitute a control circuit (not shown) through the millimeter-wave module MMW1 to provide one or more RF signals, which are transmitted through the first RF device AT2, the second RF device AT3, and the aforementioned RF trace, RF connectors, and RF cables for performing conducting a test procedure.

With the trend towards higher frequency applications in millimeter-wave technology, the RF path loss on the test load board (substrate assembly) becomes more severe. Excessive path loss can limit the strength of the signal that testing instruments can receive, causing a smaller dynamic range and thus affecting the integrity and quality of the test signal. This phenomenon is more pronounced on the load board of a semiconductor automatic test apparatus (ATE). The size of the load board is typically about 40 cm*40 cm, and the length of the RF trace on the test load board is at least several tens of centimeters, thus resulting in very significant energy loss.

As shown in FIG. 7, the first RF device AT2 and the second RF device AT3 of this embodiment have a significant difference of more than 5 dB in loss compared to the stripline. For every 10 cm (100 mm) of length, the difference translates to approximately 9 dB of loss difference (signal strength loss).

### Beneficial Effects of the Embodiments

One of the beneficial effects of the present disclosure is that the RF device and the electronic apparatus provided can effectively reduce RF energy loss, decrease the size of the RF device, and provide directional bending of the electric field of the RF signal Furthermore, the RF device and the electronic apparatus of the present disclosure can also reduce the cost of device production, thereby enhancing process efficiency.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An RF device, comprising:
a substrate assembly;
a first metal structure provided on one side of the substrate assembly; and
a metal shielding cover provided on the substrate assembly and shielding the first metal structure;
wherein the first metal structure includes a first bending structure, the first bending structure includes a first part and a second part, the second part is connected to the first part, and an included angle is defined between the second part and the first part;
wherein the substrate assembly receives an RF signal, and the RF signal is transmitted through the substrate assembly, the first metal structure, and the metal shielding cover.

2. The RF device according to claim 1, wherein the first metal structure further includes a third part connected to the second part of the first metal structure, and the first part and the third part are connected to the substrate assembly.

3. The RF device according to claim 2, wherein one side of the first metal structure is connected to an inner wall of the metal shielding cover.

4. The RF device according to claim 3, wherein the substrate assembly further includes a multilayer circuit board, a plurality of signal metal through-holes, a plurality of metal through-holes, and a solder pad, wherein the plurality of signal metal through-holes and the solder pad are provided in the multilayer circuit board of the substrate assembly.

5. The RF device according to claim 4, wherein the first part of the first metal structure includes a first notch, one side of the first metal structure is connected to the metal shielding cover, the first part of the first metal structure includes a first subsection and a second subsection on both sides of the first notch, the first subsection is connected to the solder pad and the plurality of signal metal through-holes, a distance between the first subsection and the inner wall of the metal shielding cover is 0.1 mm, and the second subsection is connected to the inner wall at one side of the metal shielding cover and a ground layer.

6. The RF device according to claim 5, wherein the third part of the first metal structure includes a second notch, the third part of the first metal structure includes a first subsection and a second subsection on both sides of the second notch, another side of the substrate assembly includes the plurality of signal metal through-holes, a plurality of ground metal through-holes, and the solder pad, the first subsection of the third part is connected to the solder pad, and the second subsection of the third part is connected to the inner wall of the metal shielding cover.

7. The RF device according to claim 6, wherein a length of the substrate assembly in a first direction is 60 mm, a thickness of the first metal structure is 0.2 mm, a width of the first metal structure is 1.05 mm, and the included angle between the second part and the first part is 90 degrees.

8. The RF device according to claim 7, wherein an internal height of the metal shielding cover is 2.75 mm, a wall thickness of the metal shielding cover is 0.15 mm, the metal shielding cover completely shields the first metal structure, the first metal structure is in an inversed U-shape, the metal shielding cover is a rectangular hollow structure, and the second part of the first metal structure is positioned in a middle position within the metal shielding cover.

9. The RF device according to claim 8, wherein a width of the first notch and the second notch is 0.1 mm, a height of the first notch and the second notch is 0.45 mm, a distance between the first metal structure and the inner wall of the metal shielding cover is 0.1 mm, a distance between the first part of the first metal structure and the inner wall of the metal shielding cover is 0.4 mm, and a distance from a junction between the first part and the second part of the first metal structure to the inner wall of the metal shielding cover is 0.1 mm.

10. An electronic apparatus, including:
a control circuit; and
at least one RF device connected to the control circuit, wherein the at least one RF device includes:
a substrate assembly;
a first metal structure provided on one side of the substrate assembly; and
a metal shielding cover provided on the substrate assembly and shielding the first metal structure;
wherein the first metal structure includes a first part, a second part, and a third part, the second part is connected to the first part, the third part is connected to the second part; wherein the first metal structure is in an inversed U-shape, and the first part and the third part of the first metal structure are connected to the substrate assembly;
wherein the control circuit provides an RF signal to the substrate assembly of the RF device, and the RF signal is transmitted through the substrate assembly, the first metal structure, and the metal shielding cover for performing a testing procedure.
